(19) United States
(12) Patent Application Publication
(10) Pub. No.: US 2026/0155810 A1
(43) Pub. Date: Jun. 4, 2026

(54) RAMP GENERATOR AND IMAGE SENSING DEVICE INCLUDING THE SAME

(71) Applicant: SK hynix Inc., Icheon-si Gyeonggi-do (KR)

(72) Inventors: Jeong Ik CHOI, Icheon-si Gyeonggi-do (KR); Gun Hee YUN, Icheon-si Gyeonggi-do (KR); Dong Ju KIM, Icheon-si Gyeonggi-do (KR); Da Hwan PARK, Icheon-si Gyeonggi-do (KR); Jun Yeong LEE, Icheon-si Gyeonggi-do (KR); Ji Hwan LEE, Icheon-si Gyeonggi-do (KR)

(73) Assignee: SK hynix Inc., Icheon-si Gyeonggi-do (KR)

(21) Appl. No.: 19/191,446

(22) Filed: Apr. 28, 2025

(30) Foreign Application Priority Data
Dec. 4, 2024 (KR) 10-2024-0178906

(51) Int. Cl. H03K 4/06; H04N 25/709

(52) U.S. Cl. CPC H03K 4/06; H04N 25/709

(57) ABSTRACT

A ramp generator, capable of generating a ramp signal from an image sensor, includes a current controller, a bias voltage generator, and a ramp signal generator. The current controller adjusts a value of a reference current applied to a first node based on a plurality of control signals, and it adjusts a value of a current applied to a second node based on some control signals from among the plurality of control signals. The bias voltage generator generates a bias voltage based on a current mirrored according to the first node and the second node. The ramp signal generator generates a ramp signal based on the bias voltage.

### CROSS-REFERENCE TO RELATED APPLICATION

The present application claims priority under 35 U.S.C. § 119(a) to Korean patent application No. 10-2024-0178906, filed on Dec. 4, 2024, which application is incorporated herein by reference in its entirety.

### TECHNICAL FIELD

The technology and implementations disclosed in this patent document generally relate to a ramp generator capable of generating a ramp signal from an image sensor.

### BACKGROUND

Generally, a Complementary Metal Oxide Semiconductor (CMOS) Image Sensor (CIS) implemented by a CMOS process has been developed to have lower power consumption, lower costs, and smaller sizes than other competitive products, such that CMOS image sensors (CISs) have been intensively researched and rapidly come into widespread use. Specifically, CMOS image sensors (CISs) have been developed to have higher image quality than other competitive products, such that the application scope of CMOS image sensors (CISs) has recently been extended to video applications that require higher resolutions and higher frame rates as compared to competitive products.

Differently from a solid-state image pickup device, a CMOS image sensor (CIS) converts analog signals (pixel signals) generated from a pixel array into digital signals. To convert analog signals into digital signals, the CMOS image sensor (CIS) has been designed to include a high-resolution Analog-to-Digital Converter (ADC).

The analog-to-digital converter (ADC) may perform correlated double sampling on an analog output voltage indicating an output signal of the pixel array, and it may store the resultant voltage. In response to a ramp signal generated by the ramp signal generator, the ADC may compare the stored voltage obtained by the correlated double sampling operation with a predetermined reference voltage (ramp signal), such that the ADC may provide a comparison signal for generating a digital code.

However, when a swing range of the ramp signal is insufficient, a conversion range of the ADC configured to receive the ramp signal as an input signal may be limited.

### SUMMARY

In accordance with an embodiment of the present disclosure, a ramp generator may include: a current controller configured to adjust a value of a reference current applied to a first node based on a plurality of control signals, and configured to adjust a value of a current applied to a second node based on some control signals from among the plurality of control signals; a bias voltage generator configured to generate a bias voltage based on a current mirrored according to the first node and the second node; and a ramp signal generator configured to generate a ramp signal based on the bias voltage.

In accordance with another embodiment of the present disclosure, an image sensing device may include: a pixel array configured to output a pixel signal by converting incident light into an electrical signal; a ramp generator configured to adjust a value of a reference current applied to a first node based on a plurality of control signals, configured to adjust a value of a current applied to a second node based on control signals of some upper bits from among the plurality of control signals, and configured to generate a ramp signal based on a mirrored current according to the first node and the second node; an analog-to-digital converter (ADC) configured to output analog-to-digital conversion data based on the pixel signal and the ramp signal; and a timing controller configured to generate the plurality of control signals.

### BRIEF DESCRIPTION OF THE DRAWINGS

The above and other features and beneficial aspects of the present disclosure will become readily apparent with reference to the following detailed description when considered in conjunction with the accompanying drawings.

FIG. 1 is a block diagram illustrating an image sensing device based on an embodiment of the present disclosure.

FIG. 2 is a circuit diagram illustrating the current generator shown in FIG. 1 based on an embodiment of the present disclosure.

FIG. 3 is a circuit diagram illustrating the current controller shown in FIG. 1 based on an embodiment of the present disclosure.

FIG. 4 is a circuit diagram illustrating another example of the current controller shown in FIG. 1 based on an embodiment of the present disclosure.

FIG. 5 is a circuit diagram illustrating the bias voltage generator shown in FIG. 1 based on an embodiment of the present disclosure.

FIG. 6 is a circuit diagram illustrating another example of the bias voltage generator shown in FIG. 1 based on an embodiment of the present disclosure.

FIG. 7 is a circuit diagram illustrating the ramp signal generator shown in FIG. 1 based on an embodiment of the present disclosure.

FIG. 8 is a block diagram illustrating an image sensing device including the ramp generator shown in FIG. 1 based on an embodiment of the present disclosure.

### DETAILED DESCRIPTION

This patent document provides implementations and examples of a ramp generator capable of generating a ramp signal from an image sensor that may be used in configurations to substantially address one or more technical or engineering issues and to mitigate limitations or disadvantages encountered in some other ramp generators. Some embodiments of the present disclosure relate to a ramp generator that can increase the swing range of a ramp signal by expanding the headroom of a current control circuit. In recognition of the issues above, the ramp generator and the image sensing device including the same according to embodiments of the present disclosure can expand the swing range of the ADC by increasing the swing range of a ramp signal.

Reference is made in detail to some embodiments of the present disclosure, examples of which are illustrated in the accompanying drawings. Wherever possible, the same reference numbers are used throughout the drawings to refer to the same or like parts. While the disclosure is open to various modifications and alternative forms, specific embodiments thereof are shown by way of example in the drawings. However, the disclosure should not be construed as being limited to the embodiments set forth herein.

Various embodiments of the present disclosure relate to a ramp generator that can increase the swing range of a ramp signal by expanding the headroom of a current control circuit. The foregoing general description and the following detailed description of the present disclosure are illustrative and explanatory and are intended to provide further explanation of the disclosure as claimed.

Hereinafter, various embodiments are described with reference to the accompanying drawings. However, the present disclosure is not limited to the specific embodiments presented herein, but includes various modifications, equivalents, and/or alternatives of the embodiments. The embodiments of the present disclosure may provide a variety of effects capable of being directly or indirectly recognized through the present disclosure.

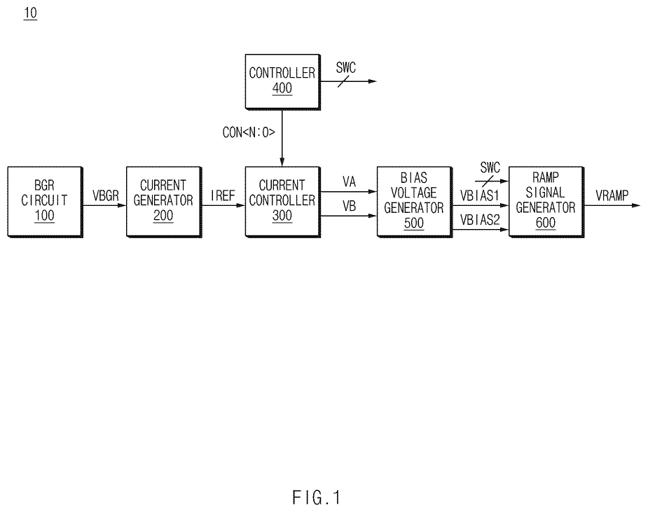

FIG. 1 is a block diagram illustrating a ramp generator 10 based on an embodiment of the present disclosure.

Referring to FIG. 1, the ramp generator 10 may generate a ramp signal (VRAMP) used for an analog-to-digital conversion operation and supply the ramp signal (VRAMP) to an analog-to-digital converter (ADC) (to be described later). For example, the ramp generator 10 may be implemented as a current steering digital-to-analog converter (DAC) capable of adjusting the gain of an image sensor by controlling the current.

The ramp generator 10 may include a bandgap reference (BGR) circuit 100, a current generator 200, a current controller 300, a controller 400, a bias voltage generator 500, and a ramp signal generator 600.

The BGR circuit 100 may generate a bandgap reference voltage (VGBR). In one example, the BGR circuit 100 may generate a bandgap reference voltage (VBGR) having a constant level that is generally unaffected or only minimally affected by changes in the manufacturing process, electrical load, time, or ambient temperature.

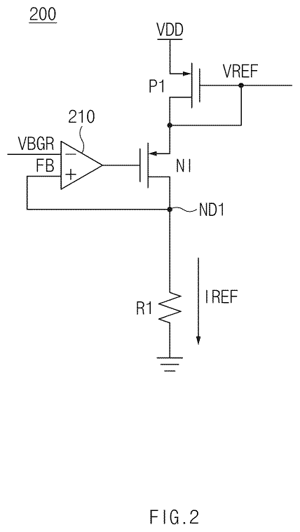

The current generator 200 may generate a reference current (IREF) based on a bandgap reference voltage (VBGR). In one example, the current generator 200 may correspond to a circuit that converts an input voltage into a current. For example, the current generator 200 may include an operational amplifier (OP-AMP)-based voltage-to-current converter, a transistor-based voltage-to-current converter, or an integrated circuit (IC)-based voltage-to-current converter, but the types of such converters are not limited thereto. A detailed configuration of the current generator 200 is described later with reference to FIG. 2.

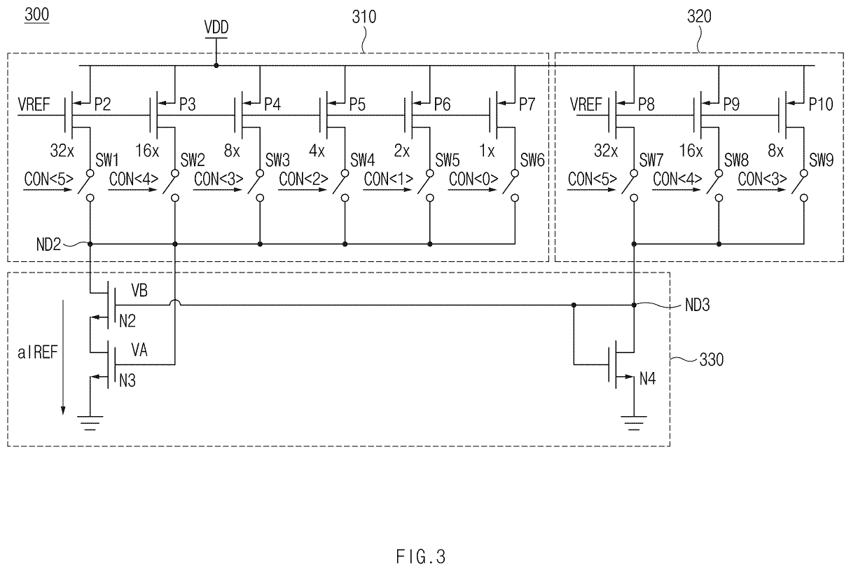

The current controller 300 may control a value of the reference current (IREF) based on a plurality of control signals (CON<N:0>). The current controller 300 may control the value of the reference current (IREF) that serves as a basis for adjusting the gain of the image sensor. For example, the current controller 300 may receive the reference current (IREF), may adjust a gain of the received reference current (IREF), and may output voltages (VA, VB) corresponding to the adjusted gain. Here, the voltages (VA, VB) may be reference voltages for determining a ramp offset voltage and/or a swing width of the ramp signal (VRAMP). A detailed configuration of the current controller 300 is described later with reference to FIG. 3.

The controller 400 may generate a plurality of control signals (CON<N:0>) for controlling the swing range of the ramp signal (VRAMP), and it may provide the plurality of control signals (CON<N:0>) to the current controller 300. In addition, the controller 400 may generate switch control signals (SWC), and it may provide the switch control signals (SWC) to the ramp signal generator 600. Although the controller 400 is illustrated as a separate component, the controller 400 may be integrated with the timing controller of the image sensor to be described later.

The controller 400 may generate a plurality of control signals (CON<N:0>) based on a digital code value that is preset by the timing controller (to be described later) to adjust the gain of the current controlled by the current controller 300 during an analog-to-digital conversion period. The controller 400 may generate switch control signals (SWC) to control the current flowing in each ramp cell (to be described later) of the ramp signal generator 600 according to the code value that is present in the timing controller (to be described later). For example, the controller 400 may selectively activate a plurality of switch control signals (SWC1 and SWC2 to be described later) when generating the ramp signal (VRAMP).

The bias voltage generator 500 may generate bias voltages (VBIAS1, VBIAS2) based on the voltages (VA, VB). The bias voltages (VBIAS1, VBIAS2) may determine a voltage level that serves as a reference for the ramp signal (VRAMP). The bias voltage generator 500 may adjust the bias voltages (VBIAS1, VBIAS2) to control the average voltage level of the ramp signal (VRAMP).

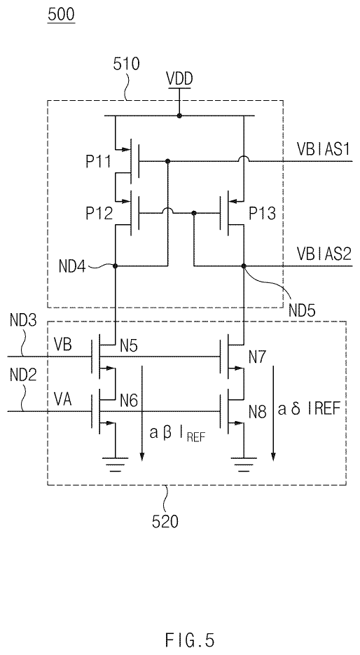

For example, the bias voltage generator 500 may include a resistor, an operational amplifier (OP-AMP), a transistor, or an IC-based current-to-voltage converter, but the type of the converter is not limited thereto. In one example, a part of the bias voltage generator 500 may form a current mirror circuit together with a part of the current controller 300. A detailed configuration of the bias voltage generator 500 is described later with reference to FIG. 5.

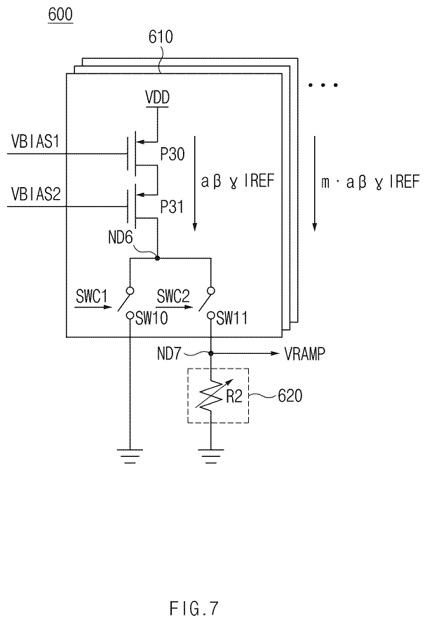

The ramp signal generator 600 may generate the ramp signal (VRAMP) based on the bias voltages (VBIAS1, VBIAS2) and switch control signals (SWC). The ramp signal generator 600 may control a waveform (e.g., a slope) of the ramp signal (VRAMP) based on the bias voltages (VBIAS1, VBIAS2) and the switch control signals (SWC). A detailed configuration of the ramp signal generator 600 is described later with reference to FIG. 7.

FIG. 2 is a circuit diagram illustrating the current generator 200 shown in FIG. 1 based on an embodiment of the present disclosure.

Referring to FIG. 2, the current generator 200 may convert the reference voltage (VREF) into the reference current (IREF) based on the bandgap reference voltage (VBGR). The current generator 200 may include a comparator 210, transistors (P1, N1), and a bias resistor (R1).

Here, the comparator 210 may compare the bandgap reference voltage (VBGR) and a feedback voltage (FB) with each other, and it may output a signal corresponding to the comparison result to the transistor (N1). The feedback voltage (FB) may be fed back from a node (ND1), and it may be applied to the comparator 210. The comparator 210 may receive the bandgap reference voltage (VBGR) through its negative (−) terminal and may receive the feedback voltage (FB) through its positive (+) terminal.

The transistor (P1) may be connected between the power-supply voltage (VDD) input terminal and the transistor (N1), and it may receive the reference voltage (VREF) through its gate terminal. For example, the transistor (P1) may be a PMOS transistor. The transistor (P1) may have a gate terminal and a drain terminal commonly connected to each other.

The transistor (N1) may be connected between the transistor (P1) and the node (ND1), and it may receive the output signal of the comparator 210 through its gate terminal. For example, the transistor (N1) may be an NMOS transistor.

The bias resistor (R1) may be connected between the node (ND1) and a ground voltage terminal. The value of the reference current (IREF) to be applied to the node (ND1) may be determined according to the output signal of the comparator 210 and the value of the resistor (R1). The reference current (IREF) applied to the node (ND1) may be mirrored and provided to the current controller 300.

FIG. 3 is a circuit diagram illustrating the current controller 300 shown in FIG. 1 based on an embodiment of the present disclosure.

Referring to FIG. 3, the current controller 300 may include a current steering circuit 310, a current adjuster 320, and a current mirroring circuit 330.

The current steering circuit 310 may adjust the value of a current to be applied to the node (ND2) based on the plurality of control signals (CON<N:0>). The current steering circuit 310 may be connected to the current generator 200 in a current mirror structure, and a copy ratio of the reference current (IREF) may be determined by a current steering operation.

The current steering circuit 310 may include a plurality of transistors (P2˜P7) and a plurality of switches (SW1˜SW6). As used herein, the tilde “˜” indicates a range of components. For example, “SW1˜SW6” indicates the switches SW1, SW2, SW3, SW4, SW5, and SW6 shown in FIG. 2.

The plurality of transistors (P2˜P7) may be connected in parallel between a power-supply voltage (VDD) input terminal and the plurality of switches (SW1˜SW6), so that the plurality of transistors (P2˜P7) may receive the reference voltage (VREF) through a common gate terminal of the plurality of transistors (P2˜P7). In an embodiment, the plurality of transistors (P2˜P7) may be implemented as PMOS transistors. In an embodiment, the plurality of transistors (P2˜P7) may have different drivabilities (i.e., driving abilities). That is, the plurality of transistors (P2˜P7) may be set to different sizes (channel sizes). The transistor (P7) corresponding to the control signal (CON<0>) of the lower bit may have the lowest drivability (channel size), and the transistor (P2) corresponding to the control signal (CON<5>) of the upper bit may have the largest drivability (channel size). That is, a transistor having a higher drivability in the direction from the lower bit to the upper bit may be driven. In another example, the plurality of transistors (P2˜P7) may be set to have the same size, however, the sizes of the transistors are not limited thereto.

The plurality of switches (SW1˜SW6) may selectively transmit voltages received from the plurality of transistors (P2˜P7) to the node (ND2) based on the plurality of control signals (CON<5:0>). In the embodiment of FIG. 3, it is assumed that “N,” which is an integer equal to or greater than “1,” is set to “5” and the number of control signals (CON<5:0>) is 6 corresponding to a total of 5 bits (i.e., a total number of digital codes is 6).

For example, the switch (SW1) may be switched according to the control signal (CON<5>) to selectively control connection between the transistor (P2) and the node (ND2). The switch (SW2) may be switched according to the control signal (CON<4>) to selectively control connection between the transistor (P3) and the node (ND2). The switch (SW3) may be switched according to the control signal (CON<3>) to selectively control connection between the transistor (P4) and the node (ND2). The switch (SW4) may be switched according to the control signal (CON<2>) to selectively control connection between the transistor (P5) and the node (ND2). The switch (SW5) may be switched according to the control signal (CON<1>) to selectively control connection between the transistor (P6) and the node (ND2). The switch (SW6) may be switched according to the control signal (CON<0>) to selectively control connection between the transistor (P7) and the node (ND2).

The current to be applied to the node (ND2) may be controlled according to the number of turned-on switches (SW1˜SW6) (or the number of turned-off switches SW1˜SW6). In the embodiment of FIG. 3, a total number of control signals (CON<5:0>) is illustrated as “6” for convenience of description. However, this embodiment is only an example, and the number of the control signals (CON<5:0>) is not limited thereto.

The plurality of switches (SW1˜SW6) may be selectively turned on or off based on the plurality of control signals (CON<5:0>). For example, digital codes of the plurality of control signals (CON<5:0>) may be input as 000000, 000001, . . . , 111111. Here, the digital codes may be provided from the timing controller (to be described later) to control the current flowing to the current steering circuit 310. For example, the code values of the above-described digital codes may be changed according to the timing controller (or the controller 400 within the timing controller).

Then, the plurality of switches (SW1˜SW6) may be sequentially turned on based on the plurality of control signals (CON<5:0>). In another example, the plurality of switches (SW 1˜SW6) may be sequentially turned off based on the plurality of control signals (CON<5:0>). In still another example, the plurality of switches (SW1˜SW6) may be randomly or specifically turned on or off in any order based on the plurality of control signals (CON<5:0>).

The current steering circuit 310 may set a multiplier using the switches (SW1˜SW6) that are turned on based on the control signals (CON<5:0>). For example, when the switch (SW6) is turned on, the gain of the node (ND2) may be controlled by a multiple of 1(1×). When the switch (SW5) is turned on, the gain of the node (ND2) may be increased by a multiple of 2(2×). When the switch (SW4) is turned on, the gain of the node (ND2) may be increased by a multiple of 4(4×). When the switch (SW3) is turned on, the gain of the node (ND2) may be increased by a multiple of 8(8×). When the switch (SW2) is turned on, the gain of the node (ND2) may be increased by a multiple of 16(16×). When the switch (SW1) is turned on, the gain of the node (ND2) may be increased by a multiple of 32(32×).

In addition, the current adjuster 320 may adjust the value of the current to be applied to the node (ND3) based on the plurality of control signals (CON<5:3>). That is, the current adjuster 320 may control the current of the node (ND3) using the control signals (CON<5:3>) of the upper 3-bits from among the plurality of control signals (CON<5:3>) applied to the current steering circuit 310. Although a presented embodiment of the present disclosure has disclosed a method for adjusting the value of a current using upper 3-bits from among the plurality of control signals (CON<5:3>), the scope or spirit of the present disclosure is not limited thereto. The number of control signals may be changed as needed in different embodiments.

The current adjuster 320 may include a plurality of transistors (P8˜P10) and a plurality of switches (SW7˜SW9).

The plurality of transistors (P8˜P10) may be connected in parallel between the power-supply voltage (VDD) input terminal and the plurality of switches (SW1˜SW6), so that the plurality of transistors (P8˜P10) may receive the reference voltage (VREF) through a common gate terminal of the plurality of transistors (P8˜P10). In an embodiment, the plurality of transistors (P8˜P10) may be implemented as PMOS transistors. In an embodiment, the plurality of transistors (P8˜P10) may have different drivabilities (i.e., driving abilities). That is, the plurality of transistors (P8˜P10) may be set to different sizes (channel sizes). The transistor (P10) corresponding to the control signal (CON<3>) of the lower bit from among the control signals (CON<5:3>) of the upper 3-bits may have the lowest drivability (channel size), and the transistor (P8) corresponding to the control signal (CON<5>) of the upper bit may have the largest drivability (channel size). That is, a transistor having a higher drivability in the direction from the lower bit to the upper bit may be driven. In another example, the plurality of transistors (P8˜P10) may be set to have the same size, however, the sizes of the transistors are not limited thereto. In some embodiments, the transistor (P8) may have the same size as the transistor (P2). The transistor (P9) may have the same size as the transistor (P3). The transistor (P10) may have the same size as the transistor (P4).

The plurality of switches (SW7˜SW9) may selectively transmit voltages received from the plurality of transistors (P8˜P10) to the node (ND3) based on the plurality of control signals (CON<5:3>). For example, the switch (SW7) may be switched according to the control signal (CON<5>) to selectively control connection between the transistor (P2) and the node (ND2). The switch (SW8) may be switched according to the control signal (CON<4>) to selectively control connection between the transistor (P9) and the node (ND3). The switch (SW9) may be switched according to the control signal (CON<3>) to selectively control connection between the transistor (P10) and the node (ND3).

The current to be applied to the node (ND3) may be controlled according to the number of turned-on switches (SW7˜SW9) (or the number of turned-off switches SW7˜SW9). The plurality of switches (SW7˜SW9) may be selectively turned on or off based on the plurality of control signals (CON<5:3>). For example, the plurality of switches (SW7˜SW9) may be sequentially turned on based on the plurality of control signals (CON<5:3>). In another example, the plurality of switches (SW7˜SW9) may be sequentially turned off based on the plurality of control signals (CON<5:3>). In still another example, the plurality of switches (SW7˜SW9) may be randomly or specifically turned on or off in any order based on the plurality of control signals (CON<5:3>).

For example, when the switch (SW9) is turned on, the gain of the node (ND3) may increase by a factor of 8(8×). When the switch (SW8) is turned on, the gain of the node (ND3) may increase by a factor of 16(16×). When the switch (SW7) is turned on, the gain of the node (ND3) may increase by a factor of 32(32×).

The current mirror circuit 330 may mirror each of the current received from the current steering circuit 310 (i.e., the current of the node ND2) and the current received from the current adjuster 320 (i.e., the current of the node ND3), and may provide the result of mirroring to the bias voltage generator 500.

The current mirror circuit 330 may include a plurality of transistors (N2˜N4). In an embodiment, the plurality of transistors (N2˜N4) may be implemented as NMOS transistors.

Transistors (N2, N3) may be connected in series between the node (ND2) and the ground voltage terminal. The transistor (N2) may receive a voltage (VB) through its gate terminal. The voltage (VB) may be a voltage received from the current adjuster 320 through the node (ND3). In addition, the transistor (N3) may receive the voltage (VA) through its gate terminal. The voltage (VA) may be a voltage received from the current steering circuit 310 through the node (ND2). The transistor (N4) may be connected between the node (ND3) and the ground voltage terminal, and it may receive the voltage (VB) through its gate terminal. The transistor (N4) may include a gate terminal and a drain terminal, which are commonly connected to the node (ND3).

When the reference current that is mirrored from the current generator 200 to the current mirror circuit 330 is denoted by “IREF,” the current to be applied to the node (ND2) may be defined as “αIREF.” That is, the gain of the current to be applied to the node (ND2) may be increased by a value (α) by adjusting the current values of the current steering circuit 310 and the current adjuster 320. For example, the value (α) may serve as a constant of proportionality between the current IREF and the current αIREF.

In the current steering circuit 310, as the multiple control signals (CON<5:3>) of the upper bits from among the multiple control signals (CON<5:0>) are activated, the gain value (α) of the current (αIREF) may increase. For the MOS transistor to operate in a saturation region, a drain-source voltage of the MOS transistor should be greater than (or equal to) zero volts “0” and a gate-source voltage of the MOS transistor should be greater than (or equal to) a threshold voltage. As the gain value of the current steering circuit 310 increases, a gate-source voltage of the transistor (N3) and a drain-source voltage of the transistor (N2) may increase. However, the drain-source voltage of the transistor (N3) serving as the bias transistor of the current mirror may decrease (e.g., to a level less than zero ‘0’) to operate in a linear region. In this case, the operating margin of the transistors (N2, N3) may decrease, so that the current may be incorrectly mirrored in the current mirror.

Accordingly, some embodiments of the present disclosure may increase a voltage value of the node (ND3) by using the current adjuster 320 operated by the multiple control signals (CON<5:3>) of the upper bits. That is, the gain of the node (ND2) may increase by the operation of the current steering circuit 310, and the voltage of the node (ND3) may increase by the current adjuster 320.

For example, the drain-source voltage of the transistor (N3) may be equal to a voltage value obtained by subtracting the gate-source voltage of the transistor (N2) from the gate-source voltage of the transistor (N4). Accordingly, as the voltage of the node (ND3) increases, the gate-source voltage level of the transistor (N4) may increase. Then, the range of the drain-source voltage of the transistor (N3) may also increase in a proportional relationship. Even if the gate-source voltage of the transistor (N3) increases, the drain-source voltage of the transistor (N3) is sufficiently guaranteed, so that the transistor (N3) may operate in the saturation region. Accordingly, a voltage headroom of the transistors (N2, N3) is expanded, so that the operating margin of the transistors (N2, N3) can be guaranteed.

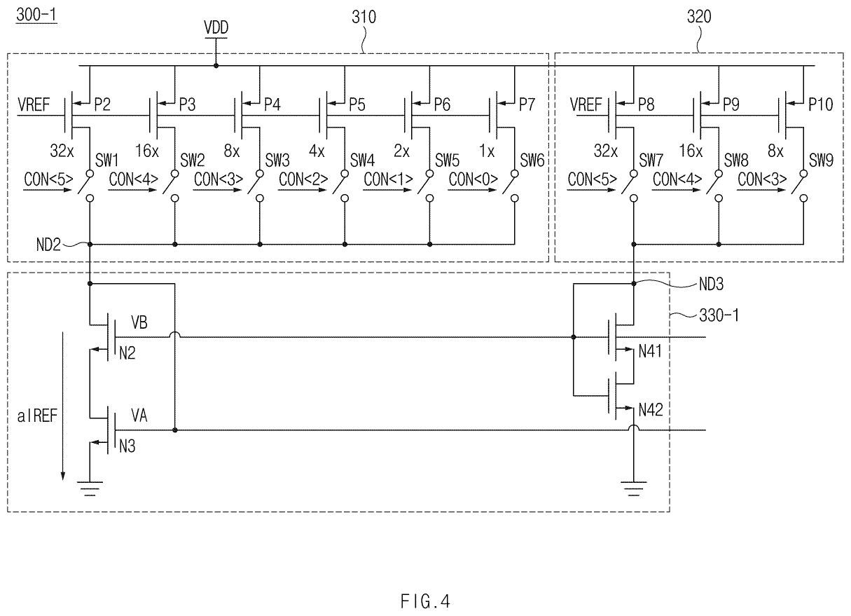

FIG. 4 is a circuit diagram illustrating another example of the current controller shown in FIG. 1 based on an embodiment of the present disclosure.

The current controller 300-1 of FIG, 4 may include a current mirror circuit 330-1 different from the current mirror circuit 330 included in the current controller 300 of FIG. 3.

For example, the current mirror circuit 330-1 may include a plurality of transistors (N2, N3, N41, N42). Here, the transistors (N41, N42) may be connected in series between the node (ND3) and the ground voltage terminal. The transistor (N41) may include a gate terminal and a drain terminal which are commonly connected to the node (ND3). The transistor (N42) may be connected to the node (ND3) through its gate terminal.

The connection relationship of the remaining components except for the transistors (N41, N42) in the current controller 300-1 having the above-described structure is the same as in FIG. 3, and as such, redundant description thereof will herein be omitted.

FIG. 5 is a circuit diagram illustrating the bias voltage generator 500 shown in FIG. 1 based on an embodiment of the present disclosure.

Referring to FIG. 5, the bias voltage generator 500 may include a voltage controller 510 and a current mirror circuit 520.

Here, the voltage controller 510 may generate bias voltages (VBIAS1, VBIAS2) based on the current of the current mirror circuit 520. The voltage controller 510 may include a plurality of transistors (P11˜P13). In an embodiment, the plurality of transistors (P11˜P13) may be implemented as PMOS transistors.

The transistors (P11, P12) may be connected between the power-supply voltage (VDD) input terminal and the node (ND4). The transistor (P11) may be connected to the node (ND4) through its gate terminal. The transistor (P12) may be connected to the node (ND5) through its gate terminal. Gate terminals of the transistor (P12) and the transistor (P13) may be commonly connected to each other. The transistor (P13) may be connected between the power-supply voltage (VDD) input terminal and the node (ND5). The gate terminal and the drain terminal of the transistor (P13) may be commonly connected to the node (ND5).

The bias voltage (VBIAS1) of the node (ND4) may be applied to the gate terminal of the transistor (P11), and it may be output to the ramp signal generator 600. The bias voltage (VBIAS2) of the node (ND5) may be applied to the gate terminals of the transistors (P12, P13), and it may be output to the ramp signal generator 600. The transistors (P12, P13) may be connected in a cascode form in which the gate terminals of the transistors (P12, P13) are commonly connected to each other.

In addition, the current mirror circuit 520 may mirror the current from the current controller 300 based on the voltages (VA, VB), and it may provide the mirrored result to the voltage provider 510. The current mirror circuit 520 may include a plurality of transistors (N5˜N8). In an embodiment, the plurality of transistors (N5˜N8) may be implemented as NMOS transistors.

The transistors (N5, N6) may be connected between the node (ND4) and the ground voltage terminal. The transistor (N5) may be connected to the node (ND3) through its gate terminal, so that the transistor (N5) may receive the voltage (VB). The transistor (N6) may be connected to the node (ND2) through its gate terminal, so that the transistor (N5) may receive the voltage (VA).

The transistors (N7, N8) may be connected between the node (ND5) and the ground voltage terminal. The transistor (N7) may be connected to the node (ND3) through its gate terminal, so that the transistor (N7) may receive the voltage (VB). The transistor (N8) may be connected to the node (ND2) through its gate terminal, so that the transistor (N8) may receive the voltage (VA). The transistor (N5) and the transistor (N7) may include gate terminals commonly connected to each other. The transistor (N6) and the transistor (N8) may include gate terminals commonly connected to each other.

The transistors (N5, N6) may be connected to the current mirror circuit 330 in a current mirror structure. Accordingly, the current (αIREF) applied to the nodes (ND2, ND3) may be mirrored to the node (ND4) using the current mirror circuit 330 as a replication source. The current to be applied to the node (ND4) may become “αβIREF” by operations of the transistors (P11˜P13). That is, the current applied to the node (ND4) may increase by the value (β) as compared to the current (αIREF) applied to the nodes (ND2, ND3).

In addition, the transistors (N7, N8) may be connected to the transistors (N5, N6) in a cascode structure. Accordingly, the current (αIREF) applied to the nodes (ND2, ND3) may be mirrored to the node (ND5) using the current mirror circuit 330 as a replication source. The current applied to the node (ND5) may become “αδIREF” by the operation of the transistors (P11˜P13). That is, the current applied to the node (ND5) may increase by the value (δ) as compared to the current (αIREF) applied to the nodes (ND2, ND3).

However, as the current generated from the transistors (P11, P12) increases, the gate voltage of the transistors (P11, P12) may increase. Then, the current (e.g., the drain voltage of the transistor P31 to be described later) generated from a ramp cell (to be described later) that receives the bias voltages (VBIAS1, VBIAS2) as input may also increase, thereby causing the voltage level of the ramp signal (VRAMP) to increase. Accordingly, the operating region of the ramp cell may become a linear region, which may cause distortion of the ramp signal (VRAMP).

Therefore, in some embodiments, the transistor (P11) may be controlled by the node (ND4). In addition, the transistors (P12, P13) may be controlled by the node (ND5). In other words, the voltages (VA, VB), each of which includes a voltage headroom expanded by the current controller 300, may be provided to the bias voltage generator 500. The bias voltages (VBIAS1, VBIAS2) of the nodes (ND4, ND5) may be controlled in response to the voltages (VA, VB). Therefore, as the voltages (VA, VB) increase, the bias voltages (VBIAS1, VBIAS2) increase, so that the current to be applied to the transistors (P11˜P13) may also increase proportionally. Accordingly, the operating margin of the transistors (P30, P31) to be described later is secured, so that the transistors (P30, P31) operate in the saturation region. As a result, the ramp signal (VRAMP) generated from the ramp cell 610 at the rear stage may expand the swing range.

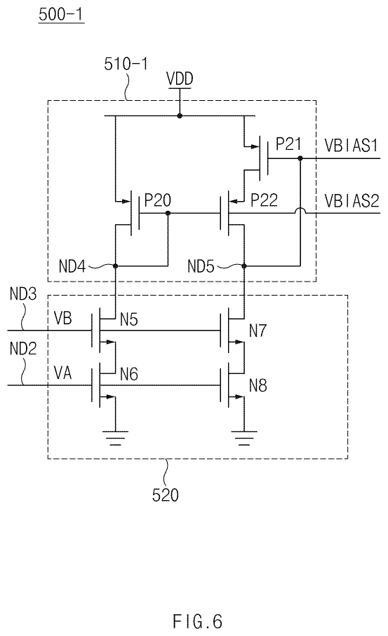

FIG. 6 is a circuit diagram illustrating another example of the bias voltage generator shown in FIG. 1 based on an embodiment of the present disclosure.

Referring to FIG. 6, the circuit of the voltage controller 510-1 of the bias voltage generator 500-1 may be different from that of the embodiment of FIG. 5.

For example, the voltage controller 510-1 of the bias voltage generator 500-1 may include a plurality of transistors (P20˜P22). In an embodiment, the plurality of transistors (P20˜P22) may be implemented as PMOS transistors.

The transistor (P20) may be connected between the power-supply voltage (VDD) input terminal and the node (ND4). The gate terminal and the drain terminal of the transistor (P20) may be commonly connected to the node (ND4). The transistors (P21, P22) may be connected in series between the power-supply voltage (VDD) input terminal and the node (ND5). The transistor (P21) may be connected to the node (ND5) through its gate terminal. The gate terminal of the transistor (P22) and the gate terminal of the transistor (P20) may be commonly connected to the node (ND4).

The bias voltage (VBIAS1) of the node (ND4) may be applied to the gate terminals of the transistors (P20, P22), and may be output to the ramp signal generator 600. The bias voltage (VBIAS2) of the node (ND5) may be applied to the gate terminal of the transistor (P21), and it may be output to the ramp signal generator 600. The transistors (P20, P22) and the transistor (P31), to be described below, may be connected to each other in a cascode form in which the gate terminals of the transistors (P20, P22, P31) are commonly connected to each other. The transistor (P21) and the transistor (P30), to be described below, may be connected to each other in a cascode form in which the gate terminals of the transistors (P21, P30) are commonly connected to each other.

The connection relationship of the remaining components except for the voltage controller 510-1 in the bias voltage generator 600-1 having the above-described structure is the same as in FIG. 5, and as such, redundant description thereof will herein be omitted. In addition, as the bias voltage generator 500-1 of FIG. 6 is applied to the image sensing device according to the present embodiment, the circuit diagram of the ramp signal generator 600 at the rear stage can also be changed, and the scope or spirit of the circuit diagram of the bias voltage generator 500-1 is not limited thereto.

FIG. 7 is a circuit diagram illustrating the ramp signal generator shown in FIG. 1 based on an embodiment of the present disclosure.

Referring to FIG. 7, the ramp signal generator 600 may include a ramp cell 610 and a load circuit 620.

The ramp cell 610 may generate a ramp signal (VRAMP) used for the analog-to-digital conversion (ADC) operation based on bias voltages (VBIAS1, VBIAS2) and switch control signals (SWC).

In some embodiments, the ramp cell 610 may be implemented as a plurality of ramp cells to share the load circuit 620. Although the present disclosure has disclosed that one load circuit 620 is shared by multiple ramp cells 610, the scope or spirit of the present disclosure is not limited thereto. For example, the number of load circuits 620 may be more than, less than, or equal to the number of ramp cells 610.

The ramp cell 610 may include a plurality of transistors (P30, P31) and a plurality of switches (SW10, SW11). In an embodiment, the transistors (P30, P31) may be implemented as PMOS transistors.

The transistors (P30, P31) may selectively supply the power-supply voltage (VDD) to the node (ND6) based on the bias voltages (VBIAS1, VBIAS2). The transistors (P30, P31) may operate as variable current sources that can adjust a microcurrent provided to node (ND6) in response to the bias voltages (VBIAS1, VBIAS2).

The transistors (P30, P31) may be connected between the power-supply voltage (VDD) input terminal and the node (ND6). The transistor (P30) may receive the bias voltage (VBIAS1) through its gate terminal. The transistor (P31) may receive the bias voltage (VBIAS2) through its gate terminal.

If the operating margin of the bias voltage generator 500 is secured, the current to be applied to the transistors (P30, P31) may be denoted by “αδγIREF.” For example, if the number of ramp cells 610 is ‘m’ (where, ‘m’ is an integer greater than or equal to ‘1’), the current to be applied to the plurality of ramp cells 610 may be denoted by “mαδγIREF.” In this case, the swing width of the ramp signal (VRAMP) may be further expanded.

The switch (SW10) may be connected between the node (ND6) and the ground voltage terminal, and the switching operation may be selectively controlled by the switch control signal (SWC1). The switch (SW11) may be connected between the node (ND6) and the load circuit 620, and the switching operation of the switch (SW11) may be selectively controlled by the switch control signal (SWC2). The plurality of ramp cells 610 may control the ramp signal (VRAMP) by adjusting the number of switches (SW10, SW11) to be connected according to the switch control signals (SWC1, SWC2).

For example, the ramp cell 610 may include the switches (SW10, SW11) that are selectively turned on (or turned off) in response to the switch control signals (SWC1, SWC2) received from the controller 400 so that the current of the ramp signal (VRAMP) can be adjusted. When the ramp signal generator 600 adjusts the slope of the ramp signal (VRAMP) in response to the bias voltages (VBIAS1, VBIAS2), the number of ramp cells 610 to be used from among the plurality of ramp cells can be adjusted according to the switch control signals (SWC1, SWC2), so that a direct current (DC) level of the ramp signal (VRAMP) can be controlled. The unused ramp cells from among the plurality of ramp cells 610 may remove a DC offset that occurs in the output node (ND6) of the ramp signal (VRAMP) because all the switches (SW10, SW11) are turned off according to the switch control signals (SWC1, SWC2).

The load circuit 620 may control loading of the ramp signal (VRAMP) generated in the ramp cell 610. Although the load circuit 620 is designed to have a variable resistor (R2) capable of changing its resistance value to perform offset adjustment, the scope or spirit of the present disclosure is not limited thereto. The variable resistor (R2) may be connected between the switch (SW11) and the ground voltage terminal so that a resistance level of the variable resistor (R2) can be adjusted. For example, the resistance level of the variable resistor (R2) may be adjusted based on a control signal received from the controller 400.

As the resistance of the load circuit 620 decreases, a gap (i.e., a swing width) between a maximum voltage level and a minimum voltage level of the ramp signal (VRAMP) may decrease. In one example, when the swing width of the ramp signal (VRAMP) is relatively small, image data corresponding to a relatively large value for the same pixel signal may be generated. In other words, the analog gain may increase. On the other hand, as the resistance of the load circuit 620 increases, the swing width of the ramp signal (VRAMP) may increase. In one example, when the swing width of the ramp signal (VRAMP) is relatively large, image data corresponding to a relatively small value for the same pixel signal may be generated. In other words, the analog gain may decrease.

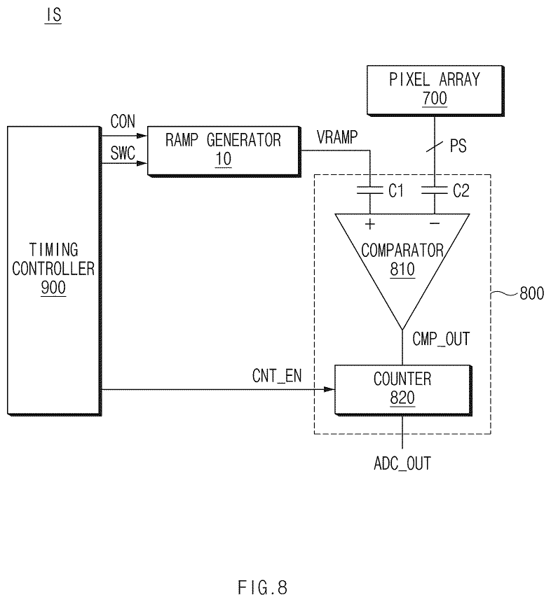

FIG. 8 is a block diagram illustrating an image sensing device (IS) that may include the ramp signal generator 600 shown in FIG. 1 based on an embodiment of the present disclosure.

Referring to FIG. 8, the image sensing device (IS) may include a ramp generator 10, a pixel array 700, an analog-to-digital converter (ADC) 800, and a timing controller 900. The components of the image sensing device (IS) illustrated in FIG. 8 are described by way of example, and this patent document encompasses numerous other changes, substitutions, variations, alterations, and modifications.

The image sensing device (IS) of FIG. 8 may include the ramp generator 10 described in the embodiments of FIGS. 1 to 7 described above. The ramp generator 10 may generate the ramp signal (VRAMP) used for the analog-to-digital conversion operation of the ADC 800 in response to a control signal (CON) received from the timing controller 900, and it may supply the ramp signal (VRAMP) to the ADC 800.

The pixel array 700 may include a plurality of imaging pixels arranged in rows and columns. In one example, the plurality of imaging pixels may be arranged in a two-dimensional (2D) pixel array including rows and columns. In another example, the plurality of imaging pixels may be arranged in a three-dimensional (3D) pixel array. The plurality of imaging pixels may convert an optical signal into an electrical signal on a unit pixel basis or a pixel group basis, where pixels in a pixel group share at least certain internal circuitry. The pixel array 700 may receive driving signals, including a row selection signal, a pixel reset signal and a transfer signal, from a row driver (not shown). Upon receiving the driving signal, corresponding imaging pixels in the pixel array 700 may be activated to perform the operations corresponding to the row selection signal, the pixel reset signal, and the transfer signal.

The ADC 800 may sequentially sample and hold voltage levels of the reference signal and the image signal, which are provided to each of a plurality of column lines from the pixel array 110. That is, the ADC 800 may sample and hold the voltage levels of the reference signal and the image signal which correspond to each of the columns of the pixel array 110. The ADC 800 may receive the ramp signal (VRAMP) from the ramp generator 10, may receive a pixel signal (PS) from the pixel array 700, and may generate and output ADC data (ADC_OUT) based on the ramp signal (VRAMP) and the pixel signal (PS). In one embodiment, the ADC 800 may be implemented as a ramp-compare type ADC that uses the ramp signal (VRAMP) of the ramp generator 10.

In some embodiments, the ADC 800 may include a first capacitor (C1), a second capacitor (C2), a comparator 810, and a counter 820.

The first capacitor (C1) may receive the ramp signal (VRAMP), and it may transmit the ramp signal (VRAMP) to the comparator 810. The second capacitor (C2) may receive a pixel signal (PS), and it may transmit the pixel signal (PS) to the comparator 810.

The comparator 810 may compare the ramp signal (VRAMP) and the pixel signal (PS) with each other, may generate comparison data (CMP_OUT) based on the comparison result, and may transmit the comparison data (CMP_OUT) to the counter 820. In some embodiments, when the ramp signal (VRAMP) is greater than the pixel signal (PS), the comparator 810 may generate comparison data (CMP_OUT) of a logic high level. In addition, when the ramp signal (VRAMP) is less than the pixel signal (PS), the comparator 810 may generate comparison data (CMP_OUT) of a logic low level. That is, the comparison data (CMP_OUT) may represent the magnitude relationship between the ramp signal (VRAMP) and the pixel signal (PS).

In some embodiments, the counter 820 may be activated in response to a counter enable signal (CNT_EN) received from the timing controller 900. The counter 820 may perform counting until the ramp signal (VRAMP) matches the analog pixel signal (PS). Then, the activated counter 820 may perform counting in response to comparison data (CMP_OUT) of a logic high level, and it may output the counting result as ADC data (ADC_OUT).

The timing controller 900 may control at least one of the ramp generator 10 and the ADC 800. The timing controller 900 may generate the control signal (CON) and the switch control signals (SWC) to control the operation of the ramp generator 10. For example, the timing controller 900 may receive digital codes for controlling the control signals (CON) from an image signal processor (ISP) (not shown), and it may store the received digital codes. In addition, the timing controller 900 may transmit, to the ramp generator 10, digital codes used to adjust the current gain when the current steering circuit 310 operates. In addition, the timing controller 900 may receive setting code values used to control the switch control signals (SWC) from the image signal processor (ISP) (not shown), and it may store the received setting code values. Whenever the ramp signal (VRAMP) is generated, the timing controller 900 may generate a setting code value for each ramp cell 610, and it may transmit the generated setting code value to the controller 400. The setting code value may also be adjusted based on the A/D (analog/digital) conversion range. For example, the setting code value may cause the timing controller 900 to generate the counter enable signal (CNT_EN) used to control the operation of the counter 820.

As is apparent from the above description, the ramp generator and the image sensing device including the same according to some embodiments of the present disclosure can expand the swing range of the ADC by increasing the swing range of a ramp signal.

Some embodiments of the present disclosure may provide a variety of effects capable of being directly or indirectly recognized through the above-mentioned patent document.

Those skilled in the art will appreciate that the present disclosure may be carried out in other specific ways than those set forth herein. In addition, claims that are not explicitly presented in the appended claims may be presented in combination as an embodiment or included as a new claim by a subsequent amendment after the application is filed.

Although a number of illustrative embodiments have been described, it should be understood that modifications and enhancements to the disclosed embodiments and other embodiments can be devised based on what is described and/or illustrated in this patent document. Therefore, the scope of the present disclosure should not be limited to the above-described embodiments but should include the equivalents thereof.

What is claimed is:

1. A ramp generator comprising:
a current controller configured to adjust a value of a reference current applied to a first node based on a plurality of control signals, and configured to adjust a value of a current applied to a second node based on some control signals from among the plurality of control signals;
a bias voltage generator configured to generate a bias voltage based on a current mirrored according to the first node and the second node; and
a ramp signal generator configured to generate a ramp signal based on the bias voltage.

2. The ramp generator according to claim 1, wherein:
the some control signals represent upper bits of the plurality of control signals.

3. The ramp generator according to claim 1, wherein the current controller includes:
a current steering circuit configured to adjust the amount of current applied to the first node based on the plurality of control signals;
a current adjuster configured to adjust the value of the current applied to the second node based on the some control signals; and
a first current mirror circuit configured to mirror the current of the first node and the current of the second node.

4. The ramp generator according to claim 3, wherein the current steering circuit includes:
a plurality of transistors each connected in parallel with each other to a power-supply voltage input terminal, and each receiving at its gate terminal a common reference voltage; and
a plurality of switches connected between the first node and the plurality of transistors such that switching operations of the switches are selectively controlled by the plurality of control signals.

5. The ramp generator according to claim 4, wherein:
the current steering circuit is configured such that a value of a current applied to the first node is adjusted through the plurality of transistors having different sizes in response to the number of turned-on switches from among the plurality of switches.

6. The ramp generator according to claim 3, wherein the current adjuster includes:
a plurality of transistors each connected in parallel with each other to a power-supply voltage input terminal, and each receiving at its gate terminal a common reference voltage; and
a plurality of switches connected between the second node and the plurality of transistors such that switching operations of the switches are selectively controlled by the some control signals.

7. The ramp generator according to claim 6, wherein:
the current adjuster is configured such that a value of a current applied to the second node is adjusted through the plurality of transistors having different sizes in response to the number of turned-on switches from among the plurality of switches.

8. The ramp generator according to claim 3, wherein the first current mirror circuit includes:
a first transistor connected between the first node and a third node and having a gate terminal connected to the second node;
a second transistor connected between the third node and a ground voltage terminal and having a gate terminal connected to the first node; and
a third transistor connected between the second node and the ground voltage terminal and having a gate terminal connected to the second node.

9. The ramp generator according to claim 3, wherein the first current mirror circuit includes:
a fourth transistor connected between the first node and a third node and having a gate terminal connected to the second node;
a fifth transistor connected between the third node and a ground voltage terminal and having a gate terminal connected to the first node;
a sixth transistor connected between the second node and a fourth node and having a gate terminal connected to the second node; and
a seventh transistor connected between the fourth node and the ground voltage terminal and having a gate terminal connected to the second node.

10. The ramp generator according to claim 1, wherein the bias voltage generator includes:
a second current mirror circuit configured to mirror one or more currents received from the first node and the second node;
a voltage controller configured to generate the bias voltage based on a value of a current of the second current mirror circuit.

11. The ramp generator according to claim 10, wherein the second current mirror circuit includes:
an eighth transistor connected between a fifth node and a sixth node and having a gate terminal connected to the second node;
a ninth transistor connected between the sixth node and a ground voltage terminal and having a gate terminal connected to the first node;
a tenth transistor connected between a seventh node and an eighth node and having a gate terminal connected to the second node; and
an eleventh transistor connected between the eighth node and the ground voltage terminal and having a gate terminal connected to the first node.

12. The ramp generator according to claim 11, wherein the voltage controller includes:
a twelfth transistor connected between a power-supply voltage input terminal and a ninth node and having a gate terminal connected to the fifth node;
a thirteenth transistor connected between the ninth node and the fifth node and having a gate terminal connected to the fifth node; and
a fourteenth transistor connected between the power-supply voltage input terminal and the seventh node and having a gate terminal connected to the seventh node.

13. The ramp generator according to claim 11, wherein the voltage controller includes:
a fifteenth transistor connected between a power-supply voltage input terminal and the fifth node and having a gate terminal connected to the fifth node;
a sixteenth transistor connected between the power-supply voltage input terminal and the tenth node and having a gate terminal connected to the seventh node; and
a seventeenth transistor connected between the tenth node and the seventh node and having a gate terminal connected to the fifth node.

14. The ramp generator according to claim 1, wherein the ramp signal generator includes:
a ramp cell configured to generate the ramp signal based on the bias voltage and a switch control signal; and
a load circuit configured to control loading of the ramp signal.

15. The ramp generator according to claim 14, wherein:
the ramp cell is implemented as a plurality of ramp cells, and the plurality of ramp cells share the load circuit.

16. The ramp generator according to claim 14, wherein the ramp cell includes:
an eighteenth transistor connected between a power-supply voltage input terminal and an eleventh node and having a gate terminal connected to a fifth node;
a nineteenth transistor connected between the eleventh node and a twelfth node and having a gate terminal connected to a seventh node;
a first switch connected between the twelfth node and a ground voltage terminal such that a switching operation of the first switch is controlled by a first switch control signal; and
a second switch connected between the twelfth node and the load circuit such that a switching operation of the second switch is controlled by a second switch control signal.

17. The ramp generator according to claim 14, wherein the load circuit includes:
a variable resistor connected between the ramp cell and a ground voltage terminal.

18. The ramp generator according to claim 1, further comprising:
a controller configured to generate switch control signals for controlling the plurality of control signals and the ramp signal generator;
a current generator configured to generate the reference current based on a bandgap reference voltage; and
a bandgap reference circuit configured to generate the bandgap reference voltage.

19. An image sensing device comprising:
a pixel array configured to output a pixel signal by converting incident light into an electrical signal;
a ramp generator configured to adjust a value of a reference current applied to a first node based on a plurality of control signals, configured to adjust a value of a current applied to a second node based on control signals of some upper bits from among the plurality of control signals, and configured to generate a ramp signal based on a mirrored current according to the first node and the second node;
an analog-to-digital converter (ADC) configured to output analog-to-digital conversion data based on the pixel signal and the ramp signal; and
a timing controller configured to generate the plurality of control signals.

20. The image sensing device according to claim 19, wherein the ramp generator includes:
a current controller configured to adjust a value of a reference current applied to the first node based on the plurality of control signals, and configured to adjust a value of a current applied to the second node based on the control signals of the some upper bits;
a bias voltage generator configured to generate a bias voltage based on the mirrored current; and
a ramp signal generator configured to generate the ramp signal based on the bias voltage, and configured to control an offset of the ramp signal based on switch control signals received from the timing controller.
